(19) United States
(12) Patent Application Publication
(10) Pub. No.: US 2019/0277485 A1
(43) Pub. Date: Sep. 12, 2019

(54) SPOT LAMP HAVING LASER

(71) Applicant: Myotek Holdings, Inc., Irvine, CA (US)

(72) Inventor: Robert T. HARRINGTON, JR., Laguna Beach, CA (US)

(21) Appl. No.: 16/294,279

(22) Filed: Mar. 6, 2019

Related U.S. Application Data
(60) Provisional application No. 62/639,536, filed on Mar. 7, 2018.
(60) Provisional application No. 62/696,948, filed on Jul. 12, 2018.

(51) Int. Cl. F21V 23/02; F21V 5/00; H05K 1/18

(52) U.S. Cl. CPC F21V 23/02; F21Y 2115/10; H05K 1/181; F21V 5/007

(57) ABSTRACT

A spot lamp includes a base including a front surface. A circuit board is positioned within the base. A laser light source is electrically coupled to the circuit board. A plurality of light sources are electrically coupled to the circuit board. The light sources are arranged around the laser light source. The circuit board operates at least one of the laser light source and the plurality of light sources.

### CROSS-REFERENCE

This application claims priority under 35 U.S.C. § 119(e) to U.S. Provisional Patent Application Ser. No. 62/639,536, filed Mar. 7, 2018, and U.S. Provisional Patent Application Ser. No. 62/696,948, filed Jul. 12, 2018, both of which are expressly incorporated by reference herein.

### TECHNICAL FIELD

The present disclosure relates generally to a spot lamp, and, more particularly, to a spot lamp having a laser.

### BACKGROUND

Spot lamps generally include at least one light source configured to generate a light beam pattern for a distance. Many spot lamps are equipped with light emitting diodes (LED) to reduce power consumption. However, beam patterns from LEDs may be limited. That is the beam pattern may be limited in distance and/or intensity. Other light sources are available to increase the intensity of the beam pattern and/or the distance of the beam pattern. Unfortunately, many of these light sources produce too much intensity or distance for a desired purpose.

### SUMMARY

According to one aspect of the disclosed embodiments, a spot lamp includes a base including a front surface. A circuit board is positioned within the base. A laser light source is electrically coupled to the circuit board. A plurality of light sources are electrically coupled to the circuit board. The light sources are arranged around the laser light source. The circuit board operates at least one of the laser light source and the plurality of light sources. The plurality of light sources are operable to generate a first light pattern having a first radiation angle. The laser light source is operable to generate a second light pattern having a second radiation angle that is less than the first radiation angle.

In some embodiments, the circuit board may operate the laser light source and the plurality of light sources simultaneously.

In some embodiments, a lens may be positioned over the laser light source.

In some embodiments, the plurality of light sources may include nine light sources. In some embodiments, each of the light sources of the plurality of light sources may be a light emitting diode. In some embodiments, a lens may be positioned over each light emitting diode.

In some embodiments, the spot lamp may be a wearable device. In some embodiments, the spot lamp may be a handheld device.

In some embodiments, a first power source may power the plurality of light sources, and a second power source may power the laser light source.

In some embodiments, a transparent cover may be coupled to the base. The plurality of light sources and the laser light source may be positioned between the base and the transparent cover.

In some embodiments, the base may be circular and the laser light source may be centered within the base.

According to another aspect of the disclosed embodiments, a spot lamp may include a base including a front surface. A circuit board may be positioned within the base. A laser light source electrically may be coupled to the circuit board. A plurality of light sources electrically may be coupled to the circuit board. The light sources may be arranged around the laser light source. A laser lens may be positioned over the laser light source. A lens may be positioned over each of the plurality of light sources. The circuit board may operate at least one of the laser light source and the plurality of light sources. The plurality of light sources may be operable to generate a first light pattern having a first radiation angle. The laser light source may be operable to generate a second light pattern having a second radiation angle that is less than the first radiation angle.

### BRIEF DESCRIPTION

The detailed description particularly refers to the following figures, in which:

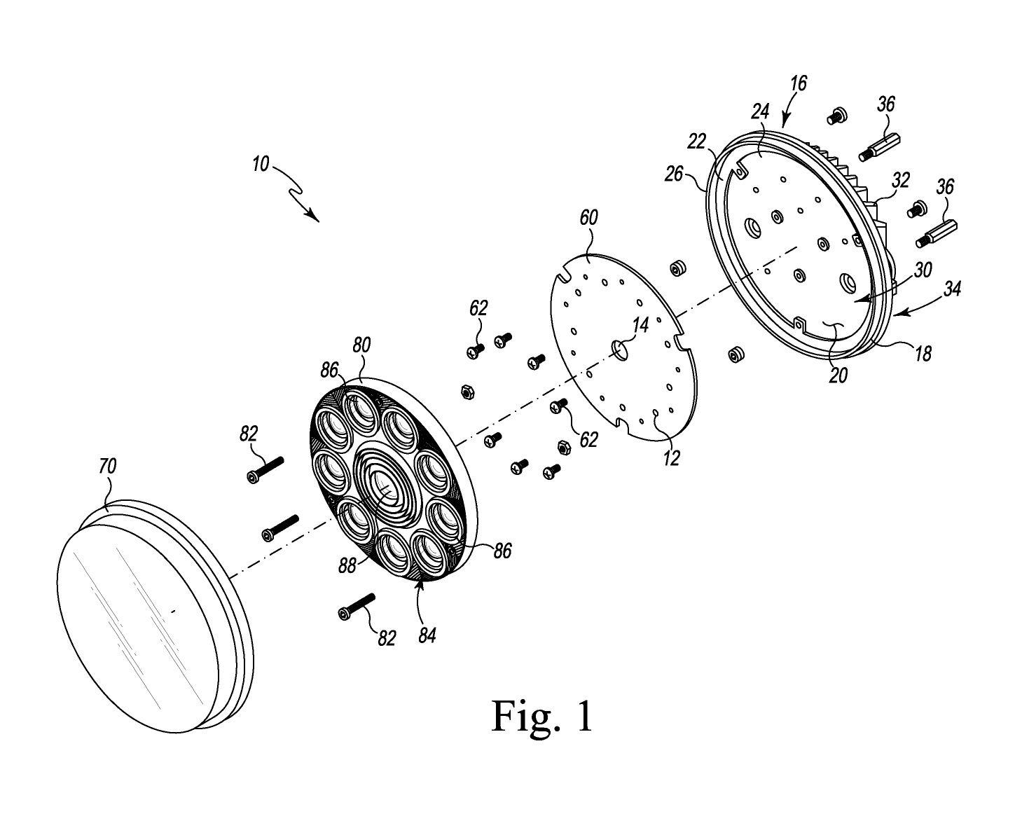

FIG. 1 is an exploded perspective view of a spot lamp of one embodiment;

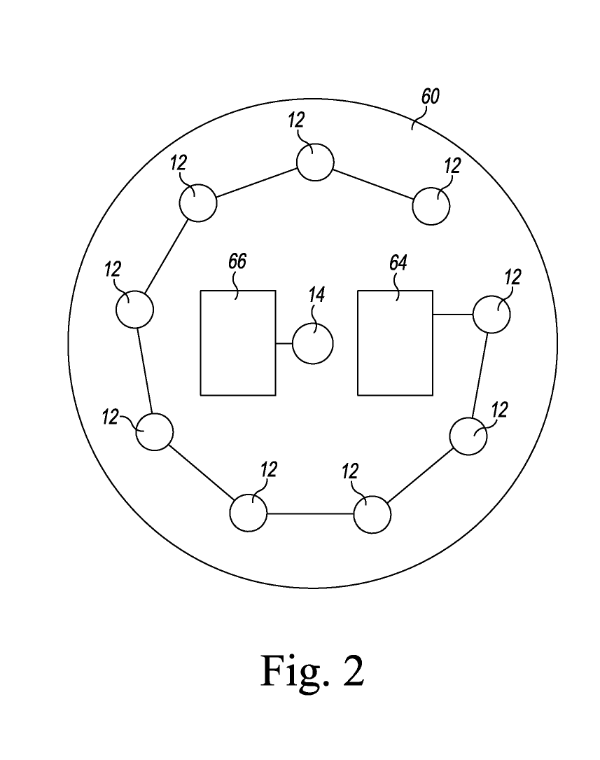

FIG. 2 is a schematic view of the circuit board shown in FIG. 1;

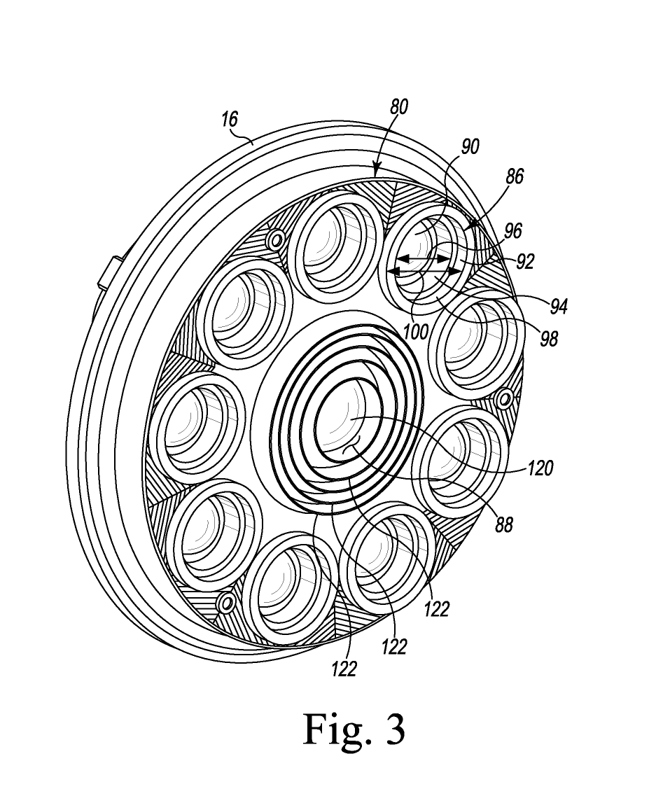

FIG. 3 is a side perspective view of the spot lamp shown in FIG. 1;

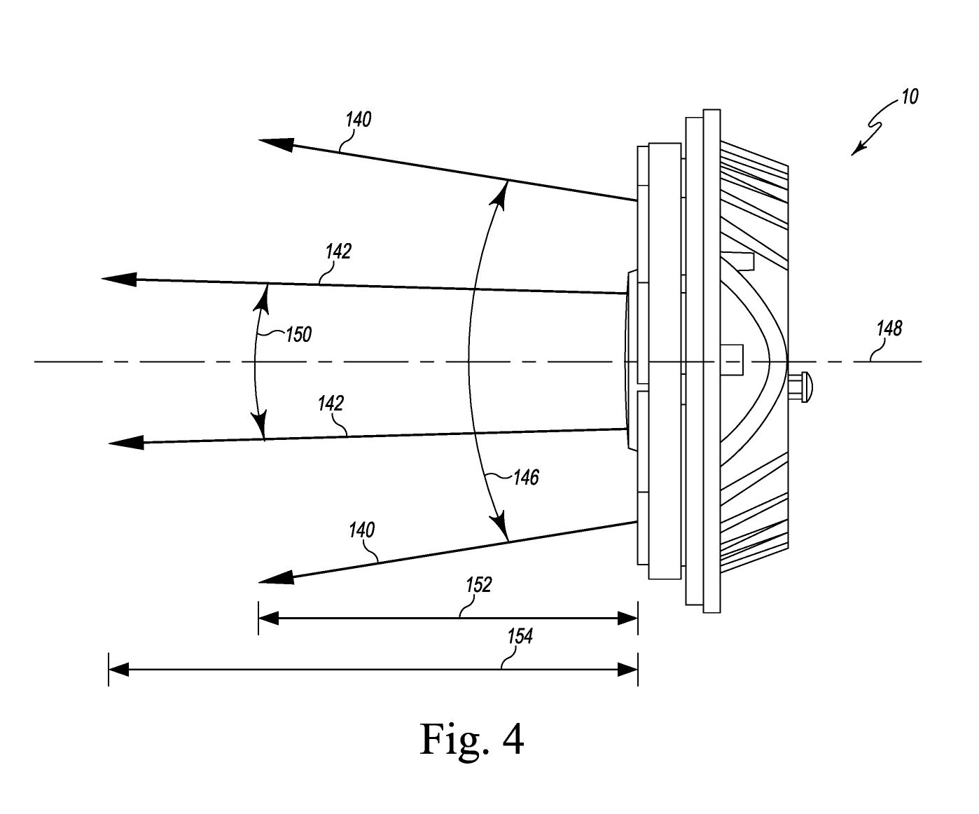

FIG. 4 is a schematic view of beam patterns generated by the spot lamp shown in FIG. 1;

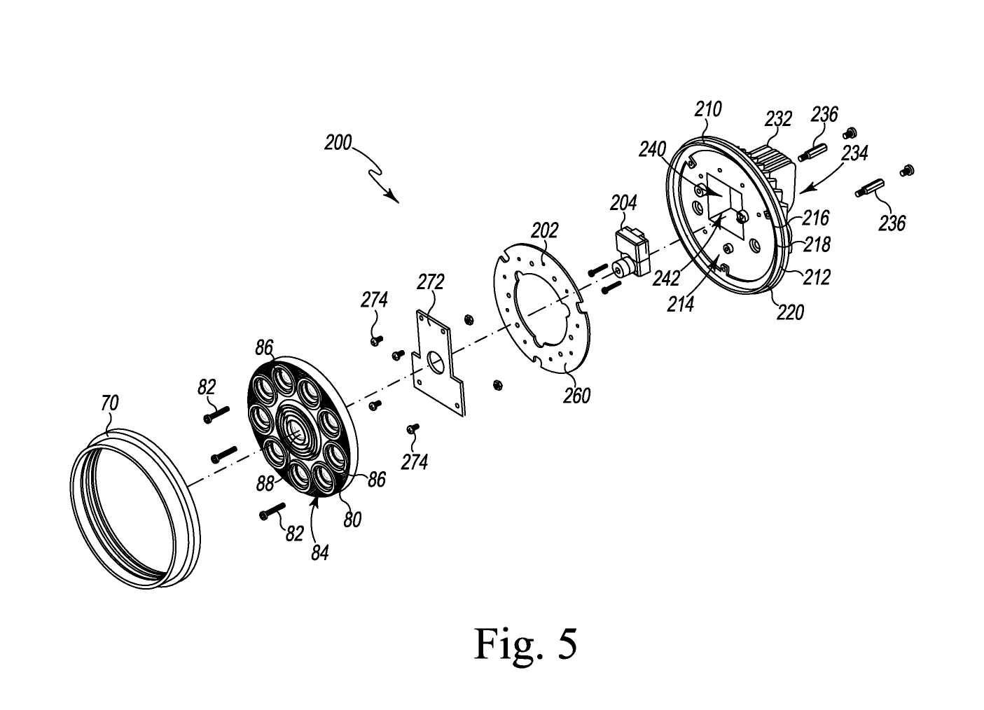

FIG. 5 is an exploded perspective view of a spot lamp of another embodiment;

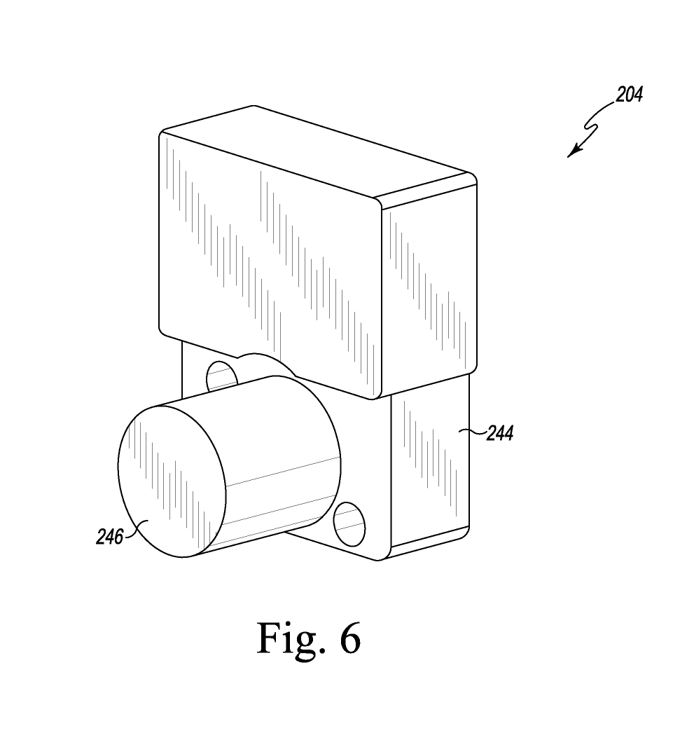

FIG. 6 is a front perspective view of the laser light source shown in FIG. 1; and

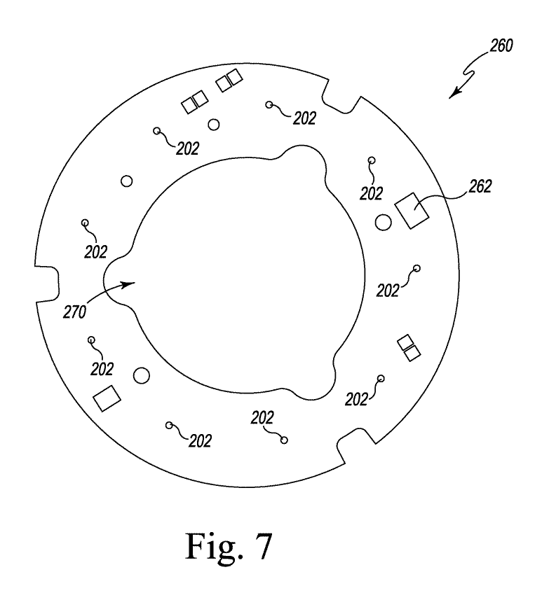

FIG. 7 is a front elevation view of the circuit board shown in FIG. 1.

### DETAILED DESCRIPTION

While the concepts of the present disclosure are susceptible to various modifications and alternative forms, specific exemplary embodiments thereof have been shown by way of example in the drawings and will herein be described in detail. It should be understood, however, that there is no intent to limit the concepts of the present disclosure to the particular forms disclosed, but on the contrary, the intention is to cover all modifications, equivalents, and alternatives falling within the spirit and scope of the invention as defined by the appended claims.

Referring to FIG. 1, a spot lamp 10 is provided with a light source 12 and a light source 14. As discussed in more detail below, the light source 12 is configured to produce a light beam having a first radiation angle. The light source 14 is configured to produce a second light beam having a second radiation angle. The radiation angle of the light beam of the light source 14 is less than the radiation angle of the light beam of the light source 12. The light beam of the light source 14 travels a greater distance than the light beam of the light source 12. Alternatively, the light beam of the light source 14 may travel the same distance or less than a distance of the light beam of the light source 12. An intensity, measured in candelas, of the light beam of the light source 14 is approximately equal to the intensity of the light beam of the light source 12. Alternatively, the intensity of the light beam of the light source 14 may be more or less than the intensity of the light beam of the light source 12. The spot lamp 10 enables a user to select the light source 12 or the light source 14 dependent on the lighting needs of the user. The light source 12 may be used independently of the light source 14. In a scenario where additional light is required, the light source 14 may be used with the light source 12 to increase an intensity of the light from the spot lamp 10. In some embodiments, using the light source 14 with the light source 12 may double the candelas of light produced by the lamp 10.

The spot lamp 10 includes a base 16 having a circular body 18 with a front surface 20. An annular rim 22 is attached to the front surface 20 and extends around an outer edge 24 of the front surface 20. The annular rim 22 includes a flange 26 extending outwardly from the front surface 20. The flange 26 cooperates with the front surface 20 to define a cavity 30 that houses various components of the spot lamp 10. The base 16 also includes a plurality of vents 32 on a back side 34 of the base 16 opposite the front surface 20. The vents 32 are configured to release pressure caused by excess heat and to prevent moisture. Terminals 36 are provided for electrical connection to a power source. For example, the base 16 may be coupled to a vehicle. The terminals 36 permit power from the vehicle to be coupled to the lamp 10.

A circuit board 60 is positioned within the cavity 30 and secured to the front surface 20 with fasteners 62. Referring to FIG. 2, the light source 12 includes a plurality of light sources 12 electrically coupled to the circuit board 60. The light sources 12 are light emitting diodes (LEDs); however, in other embodiments, other types of light sources may be contemplated, e.g. halogen bulbs, incandescent bulbs, fluorescent bulbs, or compact fluorescent bulbs. The light sources 12 are configured to generate a light beam having an intensity of approximately 200,000 to 300,000 candelas. The light sources 12 have a life span of approximately 25,000 operational hours. In the illustrative embodiment, the spot lamp 10 includes nine light sources 12; however, the spot lamp 10 may include any number of light sources 12. The light sources 12 are arranged in circle on the circuit board 60. In other embodiments, the light sources 12 may be arranged in other configurations. In some embodiments, the light sources 12 are electrically coupled to a power source, e.g. a battery, through terminals 36. For example, in an embodiment where the spot lamp 10 is coupled to a vehicle, the light sources 12 may be powered by the vehicle battery.

The light source 14 is coupled to circuit board 60 and centered within the light sources 12. In some embodiments, the light source 14 may be positioned differently with respect to the light source 12. In an exemplary embodiment, the light source 14 is a laser light configured to generate a high intensity narrow light beam in conjunction with its optics. The light source 14 is configured to generate a light beam having an intensity of approximately 250,000 candela. The light source 14 has a life span of approximately 1,000 operational hours. In some embodiments, the light source 14 is electrically coupled to a power source, e.g. a battery, through terminals 36. For example, in an embodiment where the spot lamp 10 is coupled to a vehicle, the light source 14 may be powered by the vehicle battery.

In some embodiments, the base 16 may be coupled to a handle so that the spot lamp 10 operates as a hand-held device. Further still, the base 16 may be secured to an article of clothing, such as a first responder uniform. IN such embodiments, the light source 12 is electrically couple to a battery 64 positioned on the circuit board 60, and the light source 14 is electrically coupled to a battery 66 positioned on the circuit board 60. The power sources 64 and 66 may produce a voltage in the range of 9-12 volts. In some embodiments, the circuit board 60 of the spot lamp 10 includes only a single power source to power both the light source 12 and the light source 14.

Referring back to FIG. 1 a lens panel 80 is secured to the front surface 20 of the base 16 with fasteners 82. When the lens panel 80 is secured to the base 16, the circuit board 60 is positioned between the front surface 20 and the lens panel 80. The lens panel 80 includes a front surface 84. A plurality of LED lenses 86 are formed in the front surface 84 and positioned over the light sources 12. A laser lens 88 is formed in the front surface 84 and positioned over the light source 14. A transparent cover 70 is positioned over the lens panel 80. The transparent cover 70 is secured to the flange 26 of the annular rim 22 such that the circuit board 60 and the lens panel 80 are secured within the cavity 30 defined within the base 16.

Referring to FIG. 3, each LED lens 86 includes a convex center lens 90 and stepped surfaces 92 extending around the center lens 90. The center lens 90 is recessed from the front surface 84. The stepped surfaces 92 include an inner surface 94 having a diameter 96, and an outer surface 98 having a diameter 100 that is greater than the diameter 96. The inner surface 94 is positioned proximate to the center lens 90 and is recessed from the front surface 84. The outer surface 98 extends outward from the inner surface 94 and is extended outward from the front surface 84. The center lens 90 has an aspheric profile that is rounded, but neither spherical nor cylindrical. The aspheric center lens 90 provides a wide-angle light beam from the light source 12. The stepped surfaces 92 generate total internal reflection of the light beam transmitted from the center lens 90 to facilitate reducing a loss of light waves within the light beam.

The laser lens 88 is centered within the LED lens 86 and centered within the front surface 84. The laser lens 88 includes a convex center lens 120 and a series of annular rims 122 extending circumferentially around and radially outwardly from the center lens 120. The center lens 120 has an aspheric profile that is rounded, but neither spherical nor cylindrical. The aspheric center lens 120 provides a wide-angle light beam from the light source 14. The annular rims 122 capture oblique light from the light source 14 to narrow the light beam from the light source 14. By narrowing the light beam from the light source 14, the light beam may be projected over a greater distance.

For example, referring to FIG. 4, the spot lamp 10 is configured to produce a first light beam 140 and a second light beam 142. The light beam 140 is generated by the light sources 12 and has an approximately 3-4 degree beam pattern 146 relative to a longitudinal axis 148 of the spot lamp 10. The beam pattern of the light beam 140 is produced by the aspheric center lens 90, which is configured to generate a wide-angle beam. The light beam 142 is generated by the light source 14 and has an approximately 2-3 degree beam pattern 150. Although the light beam 142 passes through aspheric center lens 120, the light beam 142 has a smaller beam pattern than the light beam 140 because the light source 14 has smaller area and the light beam 142 passes through the annular rims 122 of the laser lens 88, which collect the light waves to produce a narrower beam pattern. The light beam 140 travels a distance 152 from the spot lamp 10, and the light beam 142 travels a distance 154 from the spot lamp 10. The distance 154 that the light beam 142 travels is illustrated as being greater than the distance 152 that the light beam 140 travels. However, the light beam 140 may travel a distance greater than the light beam 142. In some embodiments, the light beams 140 and 142 travel the same distance.

During operation of the spot lamp 10, a user may select to use only light source 12 to provide a first intensity of light for a predetermined time. If the user requires additional intensity, the light source 12 may be operated with the light source 14. Operating both the light source 12 and the light 14 at the same time increases the amount of candelas produced by the lamp 10. In some embodiments the amount of candelas may approximately double when operating the light source 12 with the light source 14. Because the light source 14 generally has a shorter operational life span than the light source 12, the user typically operates the lamp 10 using only the light source 12 to conserve life span. When additional light is required, the user may opt to operate light source 14 with light sources 12 to increase the intensity of the lamp 10. Because the light source 14 has a narrower beam than the light source 12, operating the light source 14 generally adds additional intensity to a center of the light beam produced by the lamp 10.

Referring now to FIGS. 5-7, another embodiment of a spot lamp (hereinafter spot lamp 200) is shown. A number of features and components of the spot lamp 200 are the same as those described above in regard to the spot lamp 10. Features and components that are the same are identified by the same reference numbers. Referring now to FIG. 5, the spot lamp 200 is includes a light source 202 and a light source 204. As discussed in more detail below, the light source 202 is configured to produce a light beam having a first radiation angle, and the light source 204 is configured to produce a second light beam having a second radiation angle. The radiation angle of the light beam of the light source 204 is less than the radiation angle of the light beam of the light source 202. The light beam of the light source 204 travels a greater distance than the light beam of the light source 202. Alternatively, the light beam of the light source 204 may travel the same distance or less than a distance of the light beam of the light source 202. An intensity, measured in candelas, of the light beam of the light source 204 is approximately equal to the intensity of the light beam of the light source 202. Alternatively, the intensity of the light beam of the light source 204 may be more or less than the intensity of the light beam of the light source 202. The spot lamp 200 enables a user to select the light source 202 or the light source 204 dependent on the lighting needs of the user. The light source 202 may be used independently of the light source 204. In a scenario where additional light is required, the light source 204 may be used with the light source 202 to increase an intensity of the light from the spot lamp 200. In some embodiments, using the light source 204 with the light source 202 may double the candelas of light produced by the lamp 200.

The spot lamp 200 includes a heat sink 210 having a circular body 212 with a front surface 214. An annular rim 216 is attached to the front surface 214 and extends around an outer edge 218 of the front surface 214. The annular rim 216 includes a flange 220 extending outwardly from the front surface 214. The flange 220 cooperates with the front surface 214 to define a cavity 230 that houses various components of the spot lamp 200. The heat sink 210 also includes a plurality of vents 232 on a back side 234 of the heat sink 210 opposite the front surface 214. The vents 232 are configured to release pressure caused by excess heat and to prevent moisture. Terminals 236 are provided for electrical connection to a power source. For example, the heat sink 210 may be coupled to a vehicle. The terminals 236 permit power from the vehicle to be coupled to the lamp 200.

A cavity 240 extends into the heat sink 210 from an opening 242 formed in the front surface 214. The cavity 240 is configured to retain the light source 204. Referring to FIG. 6, the light source 204 is a laser light configured to generate a high intensity narrow light beam in conjunction with its optics. The laser is a μLARP Gen2+ SRS Laser Module manufactured by OSRAM GmbH, having an address of Marcel-Breuer-Strafße 6, 80807 Munich, Germany. The light source 204 is configured to generate a light beam having an intensity of approximately 250,000 candela. The light source 204 has a life span of approximately 1,000 operational hours. In some embodiments, the light source 204 is electrically coupled to a power source, e.g. a battery, through terminals 236. For example, in an embodiment where the spot lamp 200 is coupled to a vehicle, the light source 204 may be powered by the vehicle battery. The light source 204 may include a power source 244 coupled to a laser lens 246. The power source 244, which is illustratively a battery, may produce a voltage in the range of 9-12 volts. The light source 204 is positioned within the cavity 240 so that the laser lens 246 is centered with respect to the front surface 214. The light source 204 is retained within the cavity 240 via fasteners 248.

A circuit board 260 is positioned within the cavity 230 and secured to the front surface 214. Referring to FIG. 7, the light source 202 includes a plurality of light sources 202 electrically coupled to the circuit board 260. The light sources 202 are light emitting diodes (LEDs); however, in other embodiments, other types of light sources may be contemplated, e.g. halogen bulbs, incandescent bulbs, fluorescent bulbs, or compact fluorescent bulbs. The light sources 202 are configured to generate a light beam having an intensity of approximately 200,000 to 300,000 candelas. The light sources 202 have a life span of approximately 25,000 operational hours. In the illustrative embodiment, the spot lamp 200 includes nine light sources 202; however, the spot lamp 200 may include any number of light sources 202. The light sources 202 are arranged in circle on the circuit board 260. In other embodiments, the light sources 202 may be arranged in other configurations. In some embodiments, the light sources 202 are electrically coupled to a power source, e.g. a battery, through terminals 236. For example, in an embodiment where the spot lamp 200 is coupled to a vehicle, the light sources 202 may be powered by the vehicle battery.

In some embodiments, the heat sink 210 may be coupled to a handle so that the spot lamp 200 operates as a hand-held device. Further still, the heat sink 210 may be secured to an article of clothing, such as a first responder uniform. In such embodiments, the light source 202 is electrically coupled to a power source (illustratively, a battery) 262 positioned on the circuit board 260. The power source 262 may produce a voltage in the range of 9-12 volts.

An opening 270 is centered in the circuit board 260 so that the laser lens 246 extends through the opening 270. Referring back to FIG. 5, a panel 272 couples to the circuit board 260 to the heat sink 210 via fasteners 274. The panel 272 also positions over the light source 204 to further retain the light source 204 within the cavity 240.

The lens panel 80 is secured to the front surface 214 of the heat sink 210 with fasteners 82. The lens panel 80 includes each of the features shown in FIG. 3, so that the spot lamp 200 produces the first light beam 140 and a second light beam 142 illustrated in FIG. 4 in the same manner as the spot lamp 10. When the lens panel 80 is secured to the heat sink 210, the circuit board 260 is positioned between the front surface 214 and the lens panel 80. The lens panel 80 includes a front surface 84. A plurality of LED lenses 86 are formed in the front surface 84 and positioned over the light sources 202. A laser lens 88 is formed in the front surface 84 and positioned over the light source 204. A transparent cover 70 is positioned over the lens panel 80. The transparent cover 70 is secured to the flange 220 of the annular rim 216 such that the circuit board 260 and the lens panel 80 are secured within the cavity 230 defined within the heat sink 210.

During operation of the spot lamp 200, a user may select to use only light source 202 to provide a first intensity of light for a predetermined time. If the user requires additional intensity, the light source 202 may be operated with the light source 204. Operating both the light source 202 and the light source 204 at the same time increases the amount of candelas produced by the lamp 200. In some embodiments the amount of candelas may approximately double when operating the light source 202 with the light source 204. Because the light source 204 generally has a shorter operational life span than the light source 202, the user typically operates the lamp 200 using only the light source 202 to conserve life span. When additional light is required, the user may opt to operate light source 204 with light sources 202 to increase the intensity of the lamp 200. Because the light source 204 has a narrower beam than the light source 202, operating the light source 204 generally adds additional intensity to a center of the light beam produced by the lamp 200.

While the disclosure has been illustrated and described in detail in the drawings and foregoing description, such an illustration and description is to be considered as exemplary and not restrictive in character, it being understood that only illustrative embodiments have been shown and described and that all changes and modifications that come within the spirit of the disclosure are desired to be protected.

There are a plurality of advantages of the present disclosure arising from the various features of the method, apparatus, and system described herein. It will be noted that alternative embodiments of the method, apparatus, and system of the present disclosure may not include all of the features described yet still benefit from at least some of the advantages of such features. Those of ordinary skill in the art may readily devise their own implementations of the method, apparatus, and system that incorporate one or more of the features of the present invention and fall within the spirit and scope of the present disclosure as defined by the appended claims.

1. A spot lamp including:
a base including a front surface,
a circuit board positioned within the base,
a laser light source electrically coupled to the circuit board, and
a plurality of light sources electrically coupled to the circuit board, the light sources being arranged around the laser light source,
wherein the circuit board operates at least one of the laser light source and the plurality of light sources, and
wherein the plurality of light sources are operable to generate a first light pattern having a first radiation angle, and the laser light source is operable to generate a second light pattern having a second radiation angle that is less than the first radiation angle.

2. The spot lamp of claim 1, wherein the circuit board operates the laser light source and the plurality of light sources simultaneously.

3. The spot lamp of claim 1, further including a lens positioned over the laser light source.

4. The spot lamp of claim 1, wherein the plurality of light sources includes nine light sources.

5. The spot lamp of claim 1, wherein each of the light sources of the plurality of light sources is a light emitting diode.

6. The spot lamp of claim 5, further including a lens positioned over each light emitting diode.

7. The spot lamp of claim 1, wherein the spot lamp is a wearable device.

8. The spot lamp of claim 1, wherein the spot lamp is a handheld device.

9. The spot lamp of claim 1, further including:
a first power source to power the plurality of light sources, and
a second power source to power the laser light source.

10. The spot lamp of claim 1, further including a transparent cover coupled to the base, the plurality of light sources and the laser light source positioned between the base and the transparent cover.

11. The spot lamp of claim 1, wherein the base is circular and the laser light source is centered within the base.

12. A spot lamp including:
a base including a front surface,
a circuit board positioned within the base,
a laser light source electrically coupled to the circuit board,
a plurality of light sources electrically coupled to the circuit board, the light sources being arranged around the laser light source,
a laser lens positioned over the laser light source, and
a lens positioned over each of the plurality of light sources,
wherein the circuit board operates at least one of the laser light source and the plurality of light sources, and
wherein the plurality of light sources are operable to generate a first light pattern having a first radiation angle, and the laser light source is operable to generate a second light pattern having a second radiation angle that is less than the first radiation angle.

13. The spot lamp of claim 12, wherein the circuit board operates the laser light source and the plurality of light sources simultaneously.

14. The spot lamp of claim 12, wherein the plurality of light sources includes nine light sources.

15. The spot lamp of claim 12, wherein each of the light sources of the plurality of light sources is a light emitting diode.

16. The spot lamp of claim 12, wherein the spot lamp is a wearable device.

17. The spot lamp of claim 12, wherein the spot lamp is a handheld device.

18. The spot lamp of claim 12, further including:
a first power source to power the plurality of light sources, and
a second power source to power the laser light source.

19. The spot lamp of claim 12, further including a transparent cover coupled to the base, the plurality of light sources and the laser light source positioned between the base and the transparent cover.

20. The spot lamp of claim 12, wherein the base is circular and the laser light source is centered within the base.
